(19) United States
(12) Patent Application Publication
(10) Pub. No.: US 2025/0015823 A1
(43) Pub. Date: Jan. 9, 2025

(54) COMMUNICATION MODULE

(71) Applicant: Murata Manufacturing Co., Ltd., Kyoto (JP)

(72) Inventor: Yuki OHMAE, Kyoto (JP)

(21) Appl. No.: 18/890,854

(22) Filed: Sep. 20, 2024

Related U.S. Application Data
(63) Continuation of application No. PCT/JP2023/013009, filed on Mar. 29, 2023.

(30) Foreign Application Priority Data
Mar. 31, 2022 (JP) 2022-058077

(51) Int. Cl. H04B 1/18; H01P 5/18; H04B 1/04; H04B 1/16

(52) U.S. Cl. CPC H04B 1/18; H01P 5/18; H04B 1/04; H04B 1/1638; H04B 2001/0408

(57) ABSTRACT

A communication module able to have a favorable isolation characteristic is provided. The communication module includes a directional coupler inserted in a path extending toward an antenna from an amplifying part that amplifies a signal being input and a stub connected to the path. The directional coupler includes a main line and a sub line that couples with the main line and picks up a signal flowing through the main line. One end portion of the stub is connected to part of the path that is not the main line, another end portion of the stub is left open, and an extending direction of the stub from the one end portion to the other end portion is a direction moving away from the directional coupler.

### CROSS REFERENCE TO RELATED APPLICATION

This is a continuation of International Application No. PCT/JP2023/013009 filed on Mar. 29, 2023 which claims priority from Japanese Patent Application No. 2022-058077 filed on Mar. 31, 2022. The contents of these applications are incorporated herein by reference in their entireties.

### BACKGROUND ART

### Technical Field

The present disclosure relates to communication modules.

A communication module sometimes uses a directional coupler. Patent Document 1 discloses an existing directional coupler. A directional coupler disclosed in Patent Document 1 is made up of a main line and a sub line provided in parallel to the main line. One end portion of the main line is connected to a signal source, and the other end portion of the main line is connected to an antenna. Further, by detecting part of the signal from one end portion of the sub line and feeding this detected signal back to the signal source side, the magnitude of the signal transmitted from the antenna is maintained within a predetermined range.
Patent Document 1: Japanese Unexamined Patent Application Publication No. 10-22707

### BRIEF SUMMARY

Many of recent communication modules have a configuration in which an amplifying part and a directional coupler are combined. Generally, stand-alone directional couplers are designed to be able to realize desired characteristics when the characteristic impedance is 50Ω. Circuitry such as an amplifying part and the like is connected to the input terminal side of the directional coupler. In this case, if the characteristic impedance on the input terminal side that is seen from the output terminal side deviates from 50Ω, a reflection component at a boundary from the output terminal to the input terminal will increase. The directional coupler detects this reflection component, and thus, the isolation characteristic degrades.

The present disclosure provides a communication module able to have a favorable isolation characteristic.

### Solution to Problem

A communication module according to a certain aspect of the present disclosure includes: a directional coupler inserted in a path extending toward an antenna from an amplifying part that amplifies a signal being input; and a stub connected to the path, wherein the directional coupler includes a main line and a sub line that electromagnetically couples with the main line and picks up a signal flowing through the main line, one end portion of the stub is connected to part of the path that is not the main line, another end portion of the stub is left open, and an extending direction of the stub from the one end portion to the other end portion is a direction moving away from the directional coupler.

According to the communication module according to the present disclosure, a favorable isolation characteristic can be obtained.

### BRIEF DESCRIPTION OF THE DRAWINGS

FIG. 1 is a diagram illustrating an example of a communication module that serves as a premise of the present disclosure.

FIG. 2 is a diagram illustrating a configuration and operation of a directional coupler in FIG. 1.

FIG. 3 is a diagram illustrating operation of a communication module including the directional coupler illustrated in FIG. 2.

FIG. 4 is a diagram illustrating a first embodiment of a communication module according to the present disclosure.

FIG. 5 is a diagram illustrating operation of a illustrated in FIG. 4.

FIG. 6 is a diagram illustrating a communication module according to a comparative example.

FIG. 7 is a diagram illustrating operation of the communication module illustrated in FIG. 6.

FIG. 8 is a diagram illustrating an example of layout in the case where part of the communication module illustrated in FIG. 4 is arranged on a board.

FIG. 9 is a diagram illustrating an example of layout in the case where part of the communication module illustrated in FIG. 6 is arranged on a board.

FIG. 10 is a diagram illustrating an example of structure of the communication module illustrated in FIG. 9 in a thickness direction of the board.

FIG. 11 is a diagram illustrating another example of layout of the communication module.

FIG. 12 is a diagram illustrating an example of configuration of the communication module illustrated in FIG. 11 in the thickness direction of the board.

FIG. 13 is a diagram illustrating a second embodiment of the communication module of the present disclosure.

FIG. 14 is a diagram illustrating a third embodiment of the communication module of the present disclosure.

FIG. 15 is a diagram illustrating a fourth embodiment of the communication module of the present disclosure.

FIG. 16 is a diagram illustrating a fifth embodiment of the communication module of the present disclosure.

### DETAILED DESCRIPTION

Hereinafter, embodiments of communication modules of the present disclosure are described in detail with reference to the drawings. Note that the present disclosure is not limited by these embodiments. Further, constituent elements of the respective embodiments include ones that are obvious and can be replaced by a person skilled in the art or substantially identical ones. Each embodiment is for illustrative purposes only, and constituent elements illustrated in different embodiments may be combined or partially exchanged. In the description of each of the following embodiments, constituent elements identical or equivalent to those of another embodiment are denoted by the same reference characters, and descriptions thereof are simplified or omitted. The constituent elements described below can be combined if appropriate. Further, constituent elements can be omitted, replaced, or modified without departing from the scope of the present disclosure.

### (Communication Module)

For ease of understanding of embodiments, a communication module that serves as a premise of the present disclosure is described.

### [Configuration]

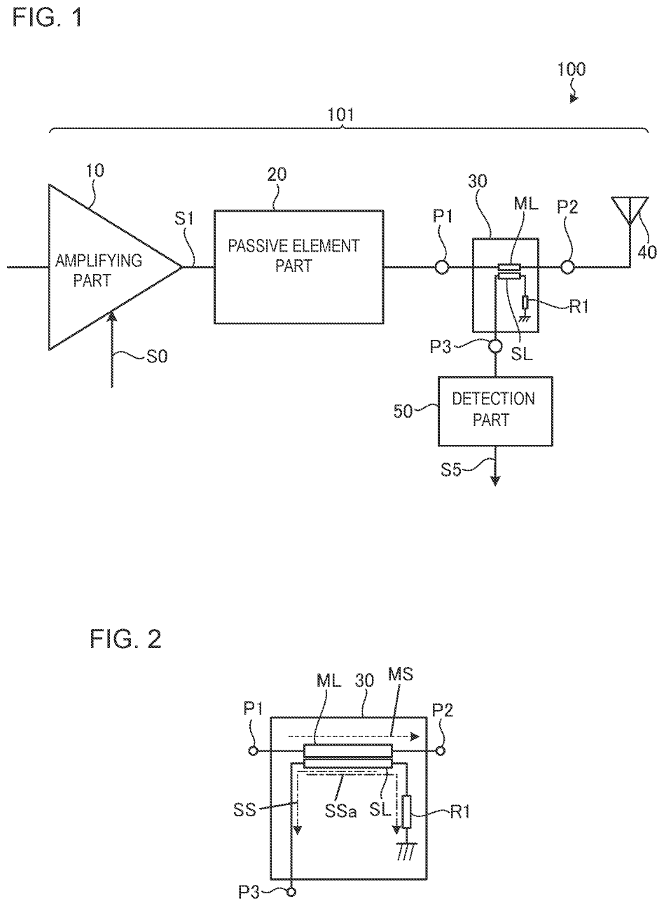

FIG. 1 is a diagram illustrating an example of a communication module that serves as the premise of the present disclosure. A communication module 100 illustrated in FIG. 1 includes an amplifying part 10, a passive element part 20, and a directional coupler 30. The communication module 100 illustrated in FIG. 1 does not include any stub in a path 101 extending from the amplifying part 10 to an antenna 40.

The amplifying part 10 amplifies a signal being input. The amplifying part 10 is, for example, a power amplifier. The passive element part 20 is connected to the output side of the amplifying part 10. The passive element part 20 is, for example, a matching circuit or a filter. The directional coupler 30 is connected to the output side of the passive element part 20. The antenna 40 and a detection part 50 are connected to the directional coupler 30. The directional coupler 30 is inserted in the path 101 that extends toward the antenna 40 from the amplifying part 10.

### (Directional Coupler)

FIG. 2 is a diagram illustrating a configuration and operation of the directional coupler 30 in FIG. 1. As illustrated in FIG. 2, the directional coupler 30 has a main line ML, a sub line SL, and a resistive element R1.

One end portion of the resistive element R1 is connected to the sub line SL. The other end portion of the resistive element R1 is connected to a reference potential. Because of this, the resistive element R1 acts as a terminal resistor. Note that the reference potential is exemplified as a ground potential but is not limited thereto in the present disclosure.

The directional coupler 30 has terminals P1, P2, and P3. The passive element part 20 is connected to the terminal P1. A signal output from the passive element part 20 is input to the terminal P1. The signal input to the terminal P1 is a main signal MS. The main signal MS flows through the main line ML and is output from the terminal P2. The antenna 40 is connected to the terminal P2. That is to say, the directional coupler 30 includes the main line ML and the sub line SL. The main line ML connects the terminal P1, which is a first terminal, and the terminal P2, which is a second terminal. The sub line SL electromagnetically couples with the main line ML and picks up a signal flowing through the main line ML.

Returning to FIG. 1, the detection part 50 is connected to the terminal P3. The detection part 50 detects a signal flowing through the sub line SL. For example, a signal S5 detected by the detection part 50 is input to a control part that is not illustrated, and a control signal S0 output from the control part is input to the amplifying part 10. The control signal S0 output from the control part controls, for example, a bias of the amplifying part 10. Note that the object of control of the control signal S0 output from the control part may be other than the bias of the amplifying part 10.

In some cases, an unwanted signal is input from the antenna 40 side due to reflection. For example, in FIG. 2, an unwanted signal SSa is input from the terminal P2 to the directional coupler 30 in some cases. This unwanted signal SSa is terminated by the resistive element R1.

### [Operation]

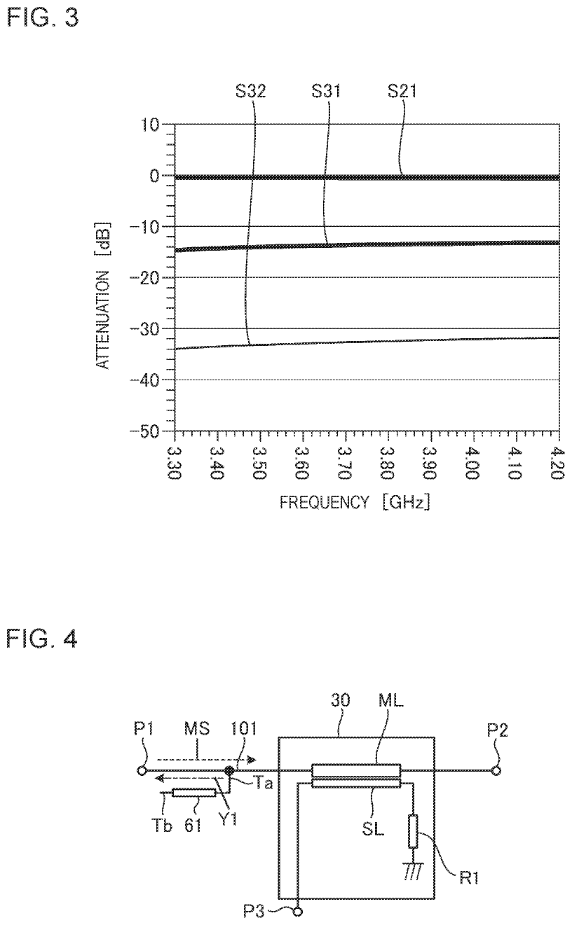

In the directional coupler 30, by electromagnetically coupling the main line ML with the sub line SL, a sub signal SS associated with the main signal MS, which flows through the main line ML, flows through the sub line SL. Because of this, the directional coupler 30 can pick up, from the terminal P3, the sub signal SS associated with the main signal MS flowing through the main line ML. FIG. 3 is a diagram illustrating operation of a illustrated in FIG. 2. FIG. 3 illustrates the relationship between the attenuation and the frequency (frequency characteristic) of each of signals S21, S31, and S32. The signal S21 is a signal that flows from the terminal P1 side to the terminal P2 side. In other words, the signal S21 is the main signal MS flowing through the main line ML. The signal S31 is a signal that flows from the terminal P1 side to the terminal P3 side. In other words, the signal S31 is the sub signal SS associated with the main signal MS flowing through the main line ML. The signal S32 is a signal that flows from the terminal P2 side to the terminal P3 side. In other words, the signal S32 is a signal that is associated with a reflected wave (unwanted signal) at the antenna 40 and is input to the main line ML. The attenuation of the signal S21 can be close to 0 [dB]. The signal S31 is an indicator indicating the degree of coupling of the directional coupler, and the signal S32 is an indicator indicating the isolation of the directional coupler. Of these signals, the signal S32 can have a largest possible attenuation.

In other words, the level (strength) of the signal S32 can be a lowest possible level.

### First Embodiment

Using the communication module described above as the premise, a communication module of the present disclosure has a stub.

### [Configuration]

FIG. 4 is a diagram illustrating the first embodiment of the communication module according to the present disclosure. FIG. 4 is a diagram illustrating part including the directional coupler 30 of the communication module. As illustrated in FIG. 4, a stub 61 is provided in the path 101. In the present example, the stub 61 is inserted between the amplifying part 10 and the directional coupler 30. The stub 61 is connected to the path 101 at part other than the main line ML of the directional coupler 30. One end portion Ta of the stub 61 is connected to the path 101. The other end portion Tb of the stub 61 is left open. The direction toward the other end portion Tb from the one end portion Ta of the stub 61 is the direction of an arrow Y1. The direction of the arrow Y1 is a direction moving away from the directional coupler 30. That is to say, the direction extending from the one end portion Ta to the other end portion Tb of the stub 61 is the direction moving away from the directional coupler 30.

An attenuation pole (not illustrated) is formed in the frequency characteristic of the signal S32 by adjusting the length or the thickness of the stub 61. This attenuation pole increases the attenuation of the signal S32 and decreases the level of the signal S32.

### [Operation]

The main signal MS flows through the path 101. The stub 61 electromagnetically couples with the path 101. The stub 61 does not electromagnetically couple with the main line ML of the directional coupler 30 but does electromagnetically couple with part of the path 101 that is other than the main line ML. The stub 61 extending in the direction opposite to the direction in which the main signal MS flows is caused to couple electromagnetically.

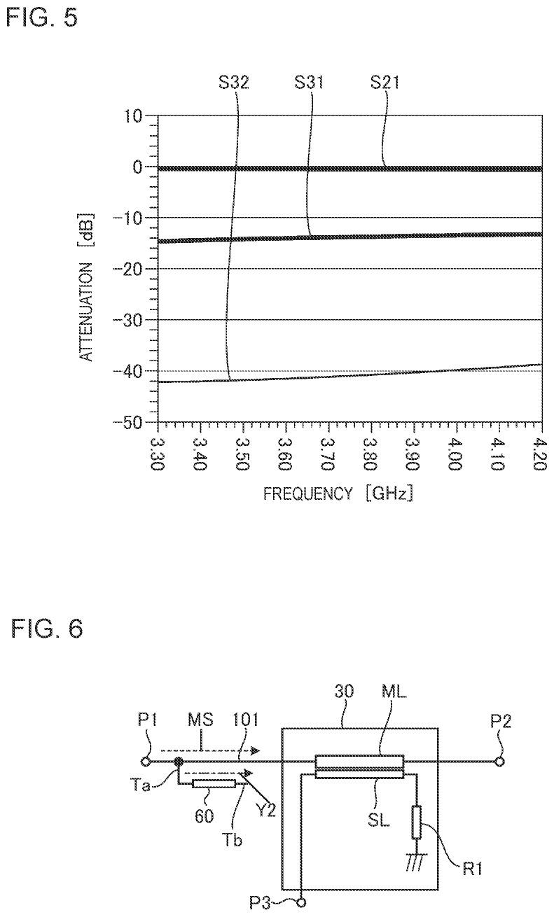

FIG. 5 is a diagram illustrating operation of a communication module including the directional coupler illustrated in FIG. 4. Referring to FIG. 5, it is found that the attenuation of the signal S32 is increased (the level is decreased) compared with the case in FIG. 3 where the stub 61 is not provided. As described above, by causing the stub 61 extending in the direction opposite to the direction in which the main signal MS flows to couple electromagnetically, an attenuation pole (not illustrated) is formed in the frequency characteristic of the signal S32. Thus, the signal S32 decreases. Because of this, the directional coupler 30 has a favorable isolation characteristic.

### Comparative Example

Next, to clarify the configuration and the effects having been described with reference to FIG. 4 and FIG. 5, a comparative example is described. FIG. 6 is a diagram illustrating a communication module according to the comparative example. FIG. 6 is a diagram illustrating part including the directional coupler 30 of the communication module. The communication module according to the comparative example is different from the case in FIG. 4 in the direction in which a stub 60 extends.

The configuration illustrated in FIG. 6 includes the stub 60. One end portion Ta of the stub 60 illustrated in FIG. 6 is connected to the path 101. The other end portion Tb of the stub 60 is left open. The direction toward the other end portion Tb from the one end portion Ta of the stub 60 is the direction of an arrow Y2. The direction of the arrow Y2 is a direction moving closer to the directional coupler 30. That is to say, the direction extending from the one end portion Ta to the other end portion Tb of the stub 60 is the direction moving closer to the directional coupler 30. As described above, the direction toward the other end portion Tb from the one end portion Ta of the stub 60 is different from that of the stub 61 in FIG. 4.

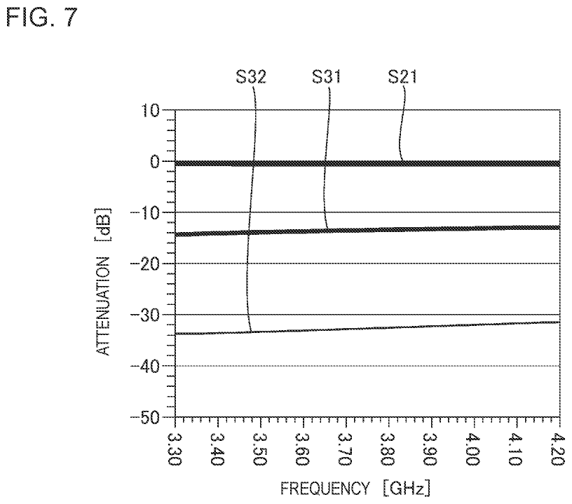

FIG. 7 is a diagram illustrating operation of the communication module illustrated in FIG. 6. Referring to FIG. 7, unlike the case in FIG. 5 where the stub 61 is provided, the attenuation of the signal S32 does not increase (the level does not decrease).

As described above, in the case in FIG. 5 where the stub 61 is provided, the stub 61 extending in the direction moving away from the directional coupler 30 is electromagnetically coupled with the path 101. Because of this, the signal S32 decreases, and a favorable isolation characteristic is obtained.

### (Example of Layout)

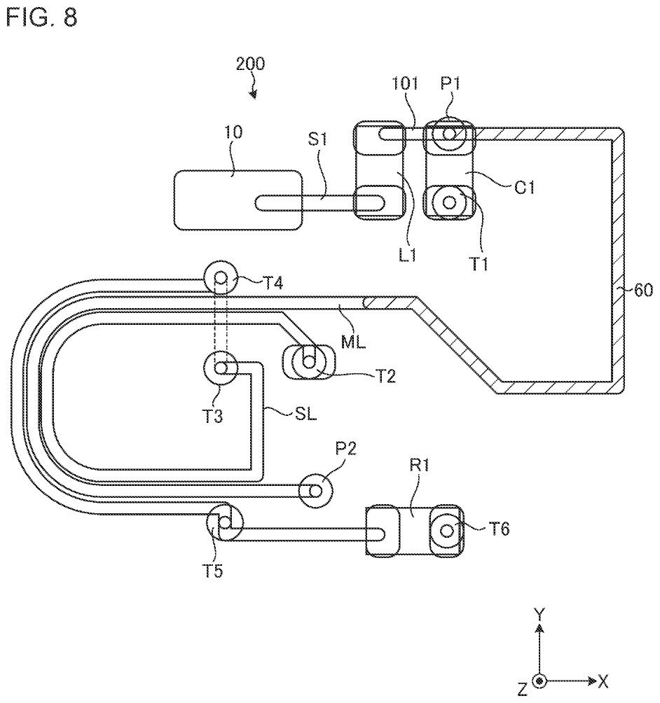

Next, an example of layout is described for the case where the communication module described above is realized on a board. FIG. 8 is a diagram illustrating an example of layout in the case where part of the communication module illustrated in FIG. 6 is arranged on a board 200. FIG. 8 illustrates an example of layout of the directional coupler and its peripheral circuitry. The present example illustrates a case where the directional coupler and its peripheral circuitry are realized using a multilayer board. In FIG. 8, patterns denoted by solid line and patterns denoted by dashed line are provided in different layers. In FIG. 8, an up-down direction is the X direction, and a right-left direction is the Y direction. The direction vertical to the surface of FIG. 8 is the Z direction. The Z direction is a direction vertical to a principal surface of the board 200 on which the communication module is mounted.

In FIG. 8, an inductor L1 and a capacitor C1 are connected between the terminal P1 and the amplifying part 10. One end portion of the capacitor C1 is connected to the terminal P1. The other end portion of the capacitor C1 is connected to a terminal T1. The terminal T1 is connected to the reference potential. The inductor L1 and the capacitor C1 act as a filter circuit.

In FIG. 8, the main line ML and the sub line SL make up a directional coupler. As illustrated in FIG. 8, the part between the terminal P1 and the terminal P2 is the main line ML. The sub line SL is provided in parallel to the main line ML.

A terminal T2 at one end portion of the sub line SL is connected to the detection part 50 which is not illustrated (see FIG. 1). The sub line SL is provided with a terminal T3 and a terminal T4. A path between the terminal T3 and the terminal T4 is connected via another layer. One end portion of the resistive element R1 is connected to a terminal T5. A terminal T6 is connected to the other end portion of the resistive element R1. The terminal T6 is connected to the reference potential. This allows the resistive element R1 to act as a terminal resistor.

In FIG. 8, a pattern corresponding to the stub 60 (corresponding to a stub pattern) is denoted by the same character “60”, and a pattern corresponding to the main line ML (corresponding to a path pattern) is denoted by the same character “101”. The same applies to stubs and paths described below. In FIG. 8, the pattern of the stub 60 is shaded by hatching. The pattern of the stub 60 and the pattern of the main line ML are formed on the same board. The pattern of the stub 60 and the pattern of the main line ML are provided on top of each other in the Z direction. The pattern of the stub 60 extends in the direction toward the terminal P2 from the terminal P1.

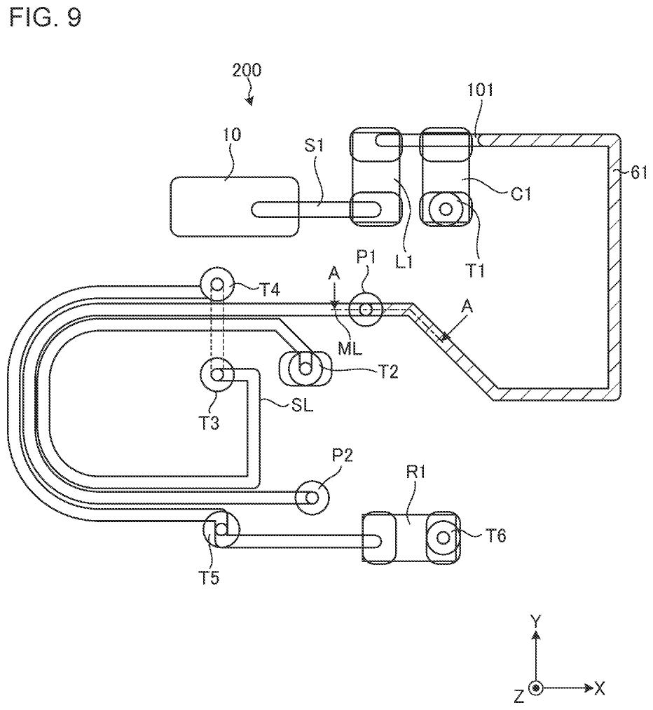

FIG. 9 is a diagram illustrating an example of layout in the case where part of the communication module illustrated in FIG. 4 is arranged on the board 200. In the present example, the communication module is also realized using a multilayer board. In FIG. 9, a pattern of the stub 61 shaded by hatching is provided on the part that is other than the main line ML formed between the terminal P1 and the terminal P2. The pattern of the stub 61 extends in the direction opposite to the direction of the stub 60 in FIG. 8. That is to say, unlike the stub 60 in FIG. 8, the pattern of the stub 61 extends in the direction moving away from the directional coupler made up of the main line ML and the sub line SL.

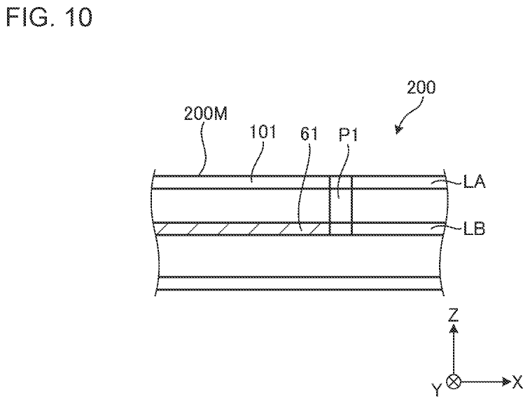

FIG. 10 is a diagram illustrating an example of structure of the communication module illustrated in FIG. 9 in a thickness direction of the board 200. FIG. 10 illustrates a cross-sectional view of A-A part in FIG. 9, that is, a cross-sectional view near the terminal P1 of the board 200. The pattern of the path 101 is electrically connected to the amplifying part 10 (see FIG. 9) mounted on a principal surface 200M of the board 200. The pattern of the path 101 is provided in a first layer LA of the board 200. The pattern of the stub 61 is provided in a second layer LB of the board 200. The pattern of the stub 61 is electrically connected to the pattern of the path 101 by the terminal P1.

As illustrated in FIG. 9 and FIG. 10, the pattern of the stub 61 is formed next to part of the pattern of the path 101 in such a way that the pattern of the stub 61 and the pattern of the path 101 overlap in the direction vertical to the principal surface 200M of the board 200 (Z direction). That is to say, the pattern of the stub 61 is provided next to the pattern of the path 101. By providing the pattern of the path 101 and the pattern of the stub 61 in different layers as illustrated in FIG. 9 and FIG. 10, a favorable isolation characteristic can be obtained while making the board 200 smaller.

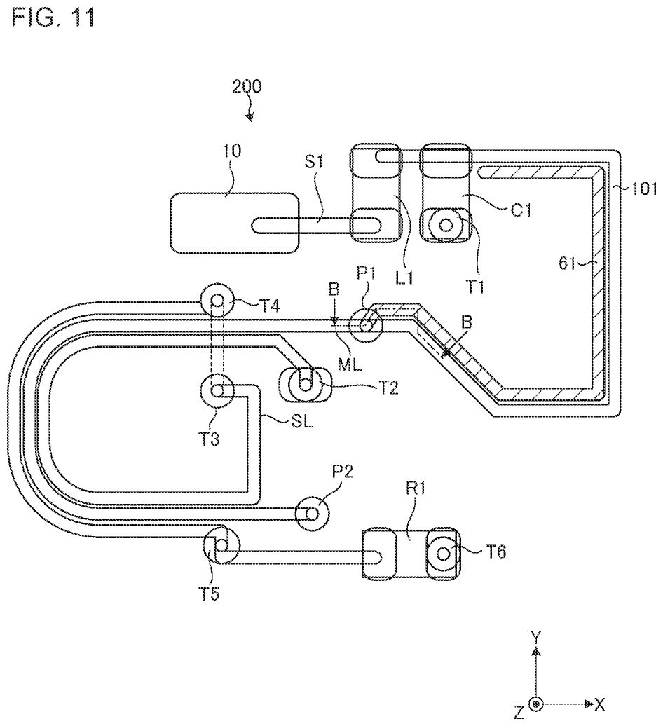

Alternatively, the pattern of the path 101 and the pattern of the stub 61 may be provided in different layers and overlap each other or may be provided in parallel to each other in the same layer. FIG. 11 is a diagram illustrating another example of layout of the communication module. FIG. 11 illustrates an example of layout in the case where the pattern of the path 101 and the pattern of the stub 61 are formed in parallel to each other in the same layer. In the present example, the communication module is also realized using a multilayer board. In FIG. 11, the pattern of the stub 61 shaded by hatching is provided in a part that is other than the main line ML formed between the terminal P1 and the terminal P2. As illustrated in FIG. 11, the pattern of the stub 61 is provided in parallel to the pattern of the path 101. The pattern of the stub 61 extends in the direction opposite to the direction of the stub 60 in FIG. 8. That is to say, as is the case in FIG. 9, the pattern of the stub 61 extends in the direction moving away from the directional coupler made up of the main line ML and the sub line SL.

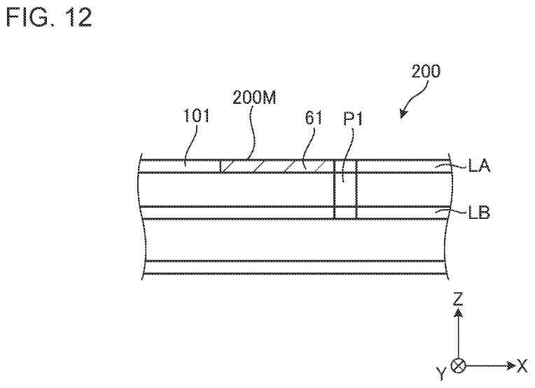

FIG. 12 is a diagram illustrating an example of configuration of the communication module illustrated in FIG. 11 in the thickness direction of the board 200. FIG. 12 illustrates a cross-sectional view of B-B part in FIG. 11, that is, a cross-sectional view near the terminal P1 of the board 200. The pattern of the path 101 is electrically connected to the amplifying part 10 (see FIG. 11) that is mounted in the principal surface 200M of the board 200. The pattern of the path 101 is provided in the first layer LA of the board 200. Similarly, the pattern of the stub 61 is also provided in the first layer LA of the board 200. The pattern of the stub 61 is electrically connected to the pattern of the path 101 by the terminal P1.

As illustrated in FIG. 11 and FIG. 12, the pattern of the stub 61 is formed next to part of the pattern of the path 101 in such a way that the pattern of the stub 61 and the pattern of the path 101 line up in the direction parallel to the principal surface 200M of the board 200.

As illustrated in FIG. 9 and FIG. 11, the pattern of the stub 61 and the pattern of the path 101 only need to couple with each other electromagnetically. Because of this, as illustrated in FIG. 9, these two patterns may be provided next to each other in such a way that these two patterns overlap in the thickness direction of the board, that is, the direction vertical to the principal surface of the board (Z direction). Further, as illustrated in FIG. 11, these two patterns may alternatively be provided next to each other in such a way that these two patterns line up in the direction parallel to the principal surface of the board (X direction or Y direction). As described above, the length or the thickness of the stub 61 are adjusted in such a manner as to form an attenuation pole in the signal S32 and decrease the level of the signal S32. Because of this, a favorable isolation characteristic can be obtained.

### Second Embodiment

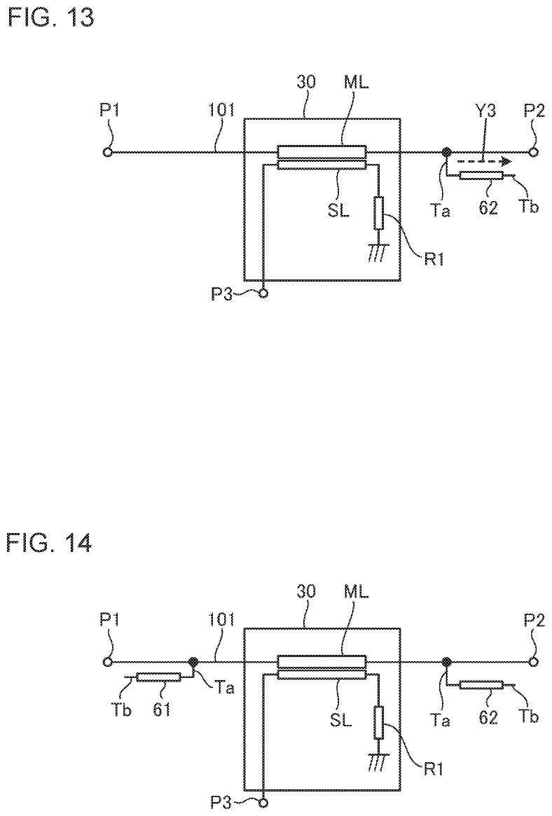

FIG. 13 is a diagram illustrating the second embodiment of the communication module of the present disclosure. FIG. 13 is a diagram illustrating part including the directional coupler 30 of the communication module. Unlike the configuration in FIG. 4, the communication module of the second embodiment illustrated in FIG. 13 does not have the stub 61 but has a stub 62. The stub 62 is connected between the directional coupler 30 and the terminal P2. Because of this, the stub 62 is inserted between the directional coupler 30 and the antenna 40. One end portion Ta of the stub 62 is connected to the path 101. The other end portion Tb of the stub 62 is left open. That is to say, the stub 62 is an open stub. The direction toward the other end portion Tb from the one end portion Ta of the stub 62 is the direction of an arrow Y3. The stub 62 extends in the direction of the arrow Y3, that is, the direction moving away from the directional coupler 30. As is the case with the first embodiment, in the present embodiment, by causing the stub 62 to couple electromagnetically, the level of the signal S32 decreases. Because of this, a favorable isolation characteristic can be obtained.

### Third Embodiment

FIG. 14 is a diagram illustrating the third embodiment of the communication module of the present disclosure. FIG. 14 is a diagram illustrating part including the directional coupler 30 of the communication module. The third embodiment of the communication module has the stubs 61 and 62. Both the stubs 61 and 62 are open stubs.

Unlike the configuration in FIG. 4, the communication module of the third embodiment illustrated in FIG. 14 further has the stub 62, in addition to the stub 61. Unlike the configuration in FIG. 13, the communication module of the third embodiment illustrated in FIG. 14 further has the stub 61, in addition to the stub 62.

As is the case in FIG. 4, the stub 61 extends in the direction moving away from the directional coupler 30. As is the case in FIG. 13, the stub 62 extends in the direction moving away from the directional coupler 30. In the communication module of the third embodiment illustrated in FIG. 14, the stubs 61 and 62 cause the level of the signal S32 to decrease. Because of this, a favorable isolation characteristic can be obtained.

### Fourth Embodiment

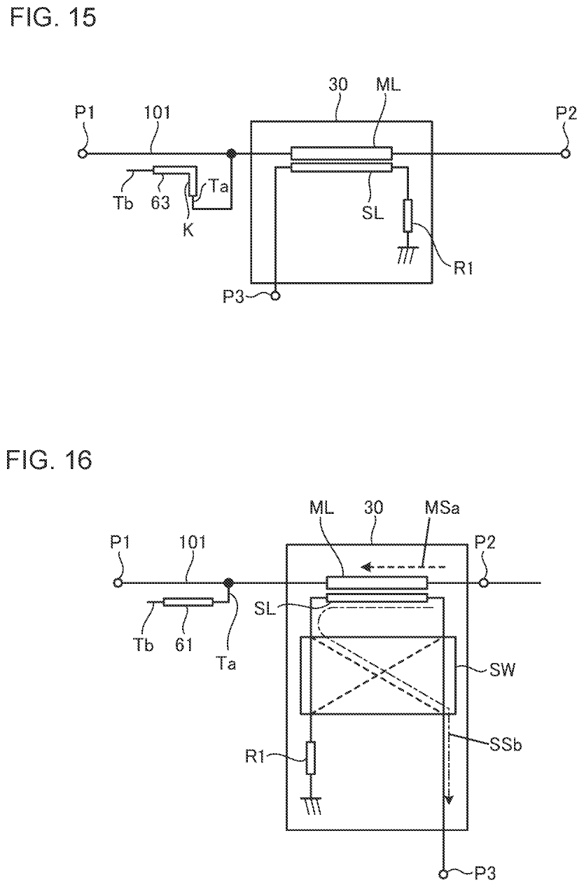

FIG. 15 is a diagram illustrating the fourth embodiment of the communication module of the present disclosure. FIG. 15 is a diagram illustrating part including the directional coupler 30 of the communication module. In FIG. 15, the entirety of a stub 63 is not necessarily electromagnetically coupled with the path 101, and only part of the stub 63 may be electromagnetically coupled with the path 101. For example, the stub 63 may have a bend part K, and this bend part K may be coupled with the path 101. That is to say, by causing at least part of the stub 63 to couple electromagnetically with the path 101, the level of the signal S32 decreases. Because of this, a favorable isolation characteristic can be obtained.

### Fifth Embodiment

FIG. 16 is a diagram illustrating the fifth embodiment of the communication module of the present disclosure. FIG. 16 is a diagram illustrating part including the directional coupler 30 of the communication module. Unlike the other communication modules, the directional coupler 30 of the communication module in FIG. 16 has a switch part SW. The switch part SW switches the direction of a signal flowing through the sub line SL. Switching the switch part SW enables the detection of a signal SSb that is based on a signal MSa input to the main line ML from the terminal P2, which is connected to the antenna 40 (see FIG. 1). In the present embodiment, by causing the stub 61 to couple electromagnetically, the level of the signal S32 also decreases. Because of this, a favorable isolation characteristic can be obtained. Note that the cases where the directional coupler 30 is provided on the output side of the amplifying part 10 such as the power amplifier (see FIG. 1) have been described. However, the stub or stubs may similarly be provided in cases where the directional coupler 30 is provided on the input side or the output side of a low-noise amplifier.

With regard to the description of Claims, the present disclosure can take the following aspects.

<1>
a communication module comprising:
a directional coupler inserted in a path extending toward an antenna from an amplifying part that amplifies a signal being input; and
a stub connected to the path, wherein
the directional coupler includes a main line and a sub line that electromagnetically couples with the main line and picks up a signal flowing through the main line,
one end portion of the stub is connected to part of the path that is not the main line,
another end portion of the stub is left open, and
an extending direction of the stub from the one end portion to the other end portion is a direction moving away from the directional coupler.
   <2>

The communication module according to <1>, wherein at least part of the stub is electromagnetically coupled with the path.

<3>

The communication module according to <1> or <2>, wherein the stub is inserted between the amplifying part and the directional coupler.

<4>

The communication module according to any one of <1> to <3>, wherein the stub is inserted between the directional coupler and the antenna.

<5>

The communication module according to any one of <1> to <4>, wherein
a path pattern that corresponds to the path and a stub pattern that corresponds to the stub are formed on a same board, and
the stub pattern is formed next to part of the path pattern.
   <6>

The communication module according to <5>, wherein the stub pattern is formed next to part of the path pattern in such a way that the stub pattern and the path pattern overlap in a direction vertical to a principal surface of the board.

<7>

The communication module according to <5>, wherein the stub pattern is formed next to part of the path pattern in such a way that the stub pattern and the path pattern line up in a direction parallel to a principal surface of the board.

<8>

The communication module according to any one of <1> to <7>, further comprising:
a switch part that switches a direction of a signal flowing through the sub line of the directional coupler.

### REFERENCE SIGNS LIST

10 Amplifying part
20 Passive element part
30 Directional coupler
40 Antenna
50 Detection part
60, 61, 62, 63 Stub
100 Communication module
200 Board
ML Main line
P1, P2, P3 Terminal
SL Sub line
SW Switch part

1. A communication module comprising:
a directional coupler in a path, the path extending toward an antenna from an amplifying part of the communication module that is configured to amplify an input signal; and
a stub connected to the path,
wherein the directional coupler comprises a main line and a sub line that is electromagnetically coupled with the main line, and that is configured to pick up a signal flowing through the main line,
wherein a first end portion of the stub is connected to a part of the path that is not the main line,
wherein a second end portion of the stub is open, and
wherein an extension direction of the stub from the first end portion to the second end portion is away from the directional coupler.

2. The communication module according to claim 1, wherein at least part of the stub is electromagnetically coupled with the path.

3. The communication module according to claim 1, wherein the stub is between the amplifying part and the directional coupler.

4. The communication module according to claim 2, wherein the stub is between the amplifying part and the directional coupler.

5. The communication module according to claim 1, wherein the stub is between the directional coupler and the antenna.

6. The communication module according to claim 2, wherein the stub is between the directional coupler and the antenna.

7. The communication module according to claim 1,
wherein a path pattern that corresponds to the path and a stub pattern that corresponds to the stub are formed on a same board, and
wherein the stub pattern is formed next to part of the path pattern on the board.

8. The communication module according to claim 2,
wherein a path pattern that corresponds to the path and a stub pattern that corresponds to the stub are formed on a same board, and
wherein the stub pattern is formed next to part of the path pattern on the board.

9. The communication module according to claim 7, wherein the stub pattern is formed next to part of the path pattern such that the stub pattern and the path pattern overlap in a direction vertical to a principal surface of the board.

10. The communication module according to claim 7, wherein the stub pattern is formed next to part of the path pattern such that the stub pattern and the path pattern line up in a direction parallel to a principal surface of the board.

11. The communication module according to claim 1, further comprising:
a switch configured to switch a direction of a signal flowing through the sub line of the directional coupler.

12. The communication module according to claim 2, further comprising:
a switch configured to switch a direction of a signal flowing through the sub line of the directional coupler.
